(19) United States
(12) Patent Application Publication
(10) Pub. No.: US 2014/0035606 A1
(43) Pub. Date: Feb. 6, 2014

(54) TEST PLATFORM

(71) Applicant: TEN-CHEN HO, Tu-Cheng (TW)

(72) Inventor: TEN-CHEN HO, Tu-Cheng (TW)

(73) Assignee: HON HAI PRECISION INDUSTRY CO., LTD., Tu-Cheng (TW)

(21) Appl. No.: 13/587,951

(22) Filed: Aug. 17, 2012

(30) Foreign Application Priority Data
Jul. 31, 2012 (CN) 201210267150X

(51) Int. Cl. G01R 31/20

(52) U.S. Cl. 324/750.25

(57) ABSTRACT

A test platform includes a supporting member, a first slide rail located below the supporting member, and a conductive second slide rail located below the first slide rail for being electrically connected to a power source. A wireless router and an uninterruptible power supply (UPS) electrically connected to the wireless router are mounted on a bottom of the supporting member. A network socket is mounted on the supporting member and electrically connected to the wireless router. A power socket is mounted on the supporting member and electrically connected to the UPS. A number of first wheels are rotatably mounted on the bottom of the supporting member. Each first wheel rests on and rolls along the first slide rail. A number of conductive second wheels are rotatably mounted on a bottom of the UPS. Each second wheel rests on and rolls along the second slide rail.

### CROSS-REFERENCE TO RELATED APPLICATION

Relevant subject matter is disclosed in a pending U.S. patent application, titled “TEST PLATFORM,” filed on Aug. 6, 2012, with the application Ser. No. 13/568,117, which is assigned to the same assignee as this patent application.

### BACKGROUND

1. Technical Field

The present disclosure relates to a test platform.

2. Description of Related Art

Electronic device undergoing electromagnetic interference (EMI) testing may be placed on a round stage. The stage includes a plurality of wheels capable of rolling along a rail so that the stage can be rotated 360 degrees. A network socket is mounted on the stage to supply network connection for the items. A power socket is mounted on the stage to supply power for the items. A cable of the network socket is connected to a network signal source away from the stage. A cable of the power socket is connected to a power source away from the stage. When the stage is rotated several laps, the cables of the power socket and the network socket may be easily tangled, and even be seriously damaged.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of a test platform.

FIG. 2 is another perspective of view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

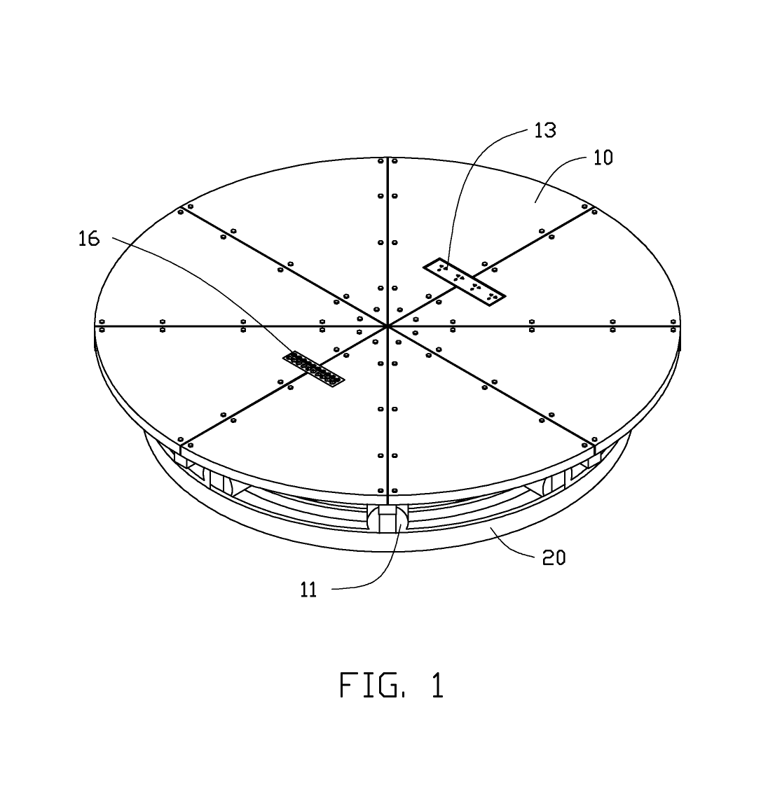

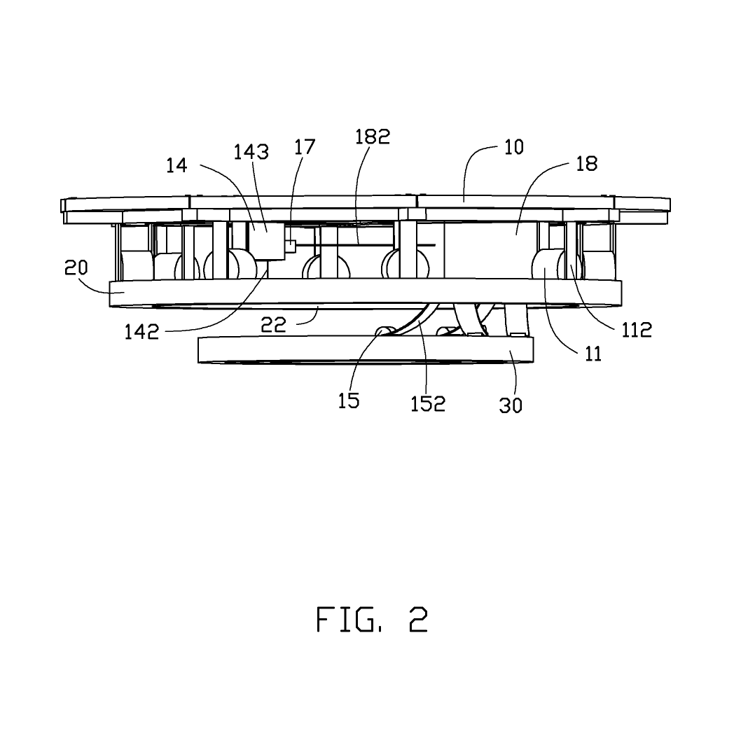

FIGS. 1 and 2 show an exemplary embodiment of a test platform to support an electronic device undergoing electromagnetic interference (EMI) testing. The test platform includes a round supporting member 10, an annular first slide rail 20 located below the supporting member 10, and an annular second slide rail 30 located below the first slide rail 20. The first slide rail 20 is coaxial with the second slide rail 30, and the outer diameter of the first slide rail 20 is greater than the outer diameter of the second slide rail 30.

A plurality of wheels 11 is rotatably mounted on a bottom of the supporting member 10. Each wheel 11 is connected to the supporting member 10 by two parallel connection poles 112. The wheels 11 rest on the first slide rail 20 and can roll along the first slide rail 20, to rotate the supporting member 10. A wireless router 14 and an uninterruptible power supply (UPS) 18 are mounted on the bottom of the supporting member 10. A network socket 16 is mounted on a top of the supporting member 10 and electrically connected to the wireless router 14, to supply a network connection for the electronic device. The wireless router 14 is covered by a metal housing 143, except for an antenna 142 of the wireless router 14 and a side of the wireless router 14 mounted on the supporting member 10. Another wireless router (not shown) away from the test platform provides network signals for the wireless router 14. A power supply filter 17 is connected between the wireless router 14 and a cable 182 of the UPS 18. A power socket 13 is mounted on the top of the supporting member 10 and electrically connected to the UPS 18, to supply power for the electronic device. A plurality of wheels 15 is rotatably mounted on front and rear sides of a bottom of the UPS 18. Each wheel 15 is connected to the UPS 18 by a connection pole 152 which extends through an opening 22 bounded by the first slide rail 20. The wheels 15 can roll along the second slide rail 30. The connection poles 152, the wheels 15, and the second slide rail 30 are electrically conductive. The second slide rail 30 is supported on a surface (not shown) and connected to a power source (not shown). Supporting material is placed on the surface to support the first slide rail 20.

The network socket 16 obtains network signals from the wireless router 14 to provide network connection for the electronic device, without the use of cable to be connected to a network signal source out of the test platform. Thus, no cable to be tangled or damaged. The frequency of the electromagnetic wave generated by the electronic device is about 30 Megahertzs to about 1000 Megahertz, and the signal frequency of the wireless router 14 is about 2400 Megahertzs, so the wireless router 14 will not disturb the EMI testing of the electronic device. The metal housing 143 can shield electromagnetic waves generated by the wireless router 14, to prevent the electromagnetic waves from disturbing the EMI testing of the electronic device. Although the UPS 18 generates power signals, the power signals that may disturb the EMI testing of the electronic device will be filtered by the power supply filter 17.

When the supporting member 10 rotates, the UPS 18 rotates with the supporting member 10 and the wheels 15 rotate along the second slide rail 30. The UPS 18 obtains power from the power source through the connection poles 152, and the wheels 15 and the second slide rail 30, and then supplies power to the power socket 13. The power socket 13 is connected to the power source without the use of cable, so there is no cable to be tangled.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A test platform, comprising:
a supporting member, wherein a wireless router and an uninterruptible power supply (UPS) electrically connected to the wireless router are mounted on a bottom of the supporting member, a network socket is mounted on the supporting member and electrically connected to the wireless router, a power socket is mounted on the supporting member and electrically connected to the UPS;
a first slide rail located below the supporting member; and
a conductive second slide rail located below the first slide rail for being electrically connected to a power source;
wherein a plurality of first wheels is rotatably mounted on the bottom of the supporting member, each first wheel rests on and rolls along the first slide rail, a plurality of conductive second wheels is rotatably mounted on a bottom of the UPS, and each second wheel rests on and rolls along the second slide rail.

2. The test platform of claim 1, wherein a power supply filter is mounted between the UPS and the wireless router.

3. The test platform of claim 1, wherein the wireless router is covered by a metal housing, except an antenna of the wireless router and a side of the wireless router mounted on the supporting member.

4. The test platform of claim 1, wherein each first wheel is connected to the supporting member by two parallel connection poles.

5. The test platform of claim 1, wherein each second wheel is connected to the UPS by a conductive connection pole.

6. The test platform of claim 1, wherein the first slide rail is annular.

7. The test platform of claim 6, wherein each second wheel is rotatably connected to the UPS by a conductive connection pole.

8. The test platform of claim 7, wherein the conductive connection pole extends through an opening bounded by the first slide rail.

9. The test platform of claim 1, wherein the second slide rail is annular.
